(19) United States
(12) Patent Application Publication
(10) Pub. No.: US 2025/0349563 A1
(43) Pub. Date: Nov. 13, 2025

(54) SUBSTRATE PROCESSING APPARATUS AND SUBSTRATE PROCESSING METHOD

(71) Applicant: SEMES CO., LTD., Cheonan-si (KR)

(72) Inventors: Eun Seok KIM, Asan-si (KR); Seung Hoon OH, Cheonan-si (KR); Hyung Gyu KIM, Ansan-si (KR); Hye Bin GWON, Cheonan-si (KR)

(73) Assignee: SEMES CO., LTD., Cheonan-si (KR)

(21) Appl. No.: 19/203,367

(22) Filed: May 9, 2025

(30) Foreign Application Priority Data
May 10, 2024 (KR) 10-2024-0061959

(51) Int. Cl. H01L 21/67; H01L 21/687

(52) U.S. Cl. CPC H01L 21/67034; H01L 21/68735; H01L 21/6875

(57) ABSTRACT

Provided is an apparatus for processing a substrate. The apparatus includes: a first body; a second body that is combined with the first body to define the treatment space; a lifting unit for moving the second body between an open position and a closed position; and a first substrate support installed in the first body and a second substrate support installed in the second body, in which a groove is formed in an edge region of a lower wall of the second body, and the first substrate support is positioned in the groove when the second body moves to the closed position. According to an embodiment of the present invention, when the substrate is dried, the substrate may be uniformly treated by uniformly forming a flow of a fluid flowing on the substrate.

### CROSS-REFERENCE TO RELATED APPLICATIONS

This application claims priority to and the benefit of Korean Patent Application No. 10-2024-0061959 filed in the Korean Intellectual Prope Office on May 10, 2024, the entire contents of which are incorporated herein by reference.

### TECHNICAL FIELD

The present invention relates to a substrate processing apparatus, and more particularly to an apparatus for processing a substrate by using a supercritical fluid.

### BACKGROUND ART

As the design rules of integrated circuit devices decrease, processes for forming deep and narrow patterns with high aspect ratios and accompanying cleaning and drying processes are required. In particular, methods have been proposed that utilize supercritical fluids to perform predetermined treatment processes, such as etching, cleaning and drying, on a substrate having a pattern with a high aspect ratio.

In one example, the cleaning process is carried out by cleaning an upper surface of the substrate with a volatile organic compound, and the drying process is carried out by supplying a fluid containing carbon dioxide (CO₂) in a supercritical state, or by supplying the fluid in a gaseous state and then changing the phase to a supercritical state to remove the volatile organic compound remaining on the substrate.

In a typical drying process, the fluid is supplied from the lower portion of the chamber, and the supplied fluid flows from the edge region of the substrate to the center region. In order to uniformly dry the substrate, the fluid must flow uniformly on the substrate.

FIG. 1 is a diagram schematically illustrating the treatment of a substrate in a typical drying chamber, and FIG. 2 is a diagram schematically illustrating the flow of a fluid on the substrate of FIG. 1. Referring to FIGS. 1 and 2, when a fluid stored in a storage source 1 is supplied to a drying chamber 3 via a lower supply line 2, and a substrate support 4 supports an edge region of a substrate W on a side of the substrate W, there is a problem that the flow of the fluid is obstructed and the fluid does not flow uniformly on the substrate.

### SUMMARY OF THE INVENTION

The present invention has been made in an effort to provide a substrate processing apparatus and a substrate processing method capable of uniformly drying a substrate when the substrate is dry treated.

The present invention has also been made in an effort to provide a substrate processing apparatus and a substrate processing method capable of uniformly forming a flow of a fluid on a substrate when the substrate is dry treated.

The present invention has also been made in an effort to provide a substrate processing apparatus and a substrate processing method in which a support supporting an edge region of a substrate does not obstruct the flow of a fluid when the substrate is dry treated.

The problem to be solved by the present invention is not limited to the above-mentioned problems, and the problems not mentioned will be clearly understood by those skilled in the art from the descriptions below.

An exemplary embodiment of the present invention, an apparatus for processing a substrate, the apparatus comprising: a chamber for providing a treatment space for processing a substrate; a fluid supply unit for supplying a fluid into the treatment space; an exhaust unit for exhausting the fluid from the treatment space; a first substrate support which is placed in the treatment space and on which a robot transferring the substrate seats the substrate; and a second substrate support which is placed in the treatment space and supports the substrate while the substrate is being treated in the treatment space, wherein the chamber includes: a first body; a second body that is combined with the first body to define the treatment space; and a lifting member for moving the second body relative to the first body, and the lifting member moves the second body between an open position and a closed position, the open position is a position where the substrate is loaded into the treatment space or unloaded from the treatment space by opening the treatment space, the closed position is a position where the treatment space is sealed to treat the substrate, the first substrate support includes: a plurality of fixing rods installed in the chamber; and a holder which is installed on the rod and on which the substrate is placed, the second substrate support includes a support plate opposite to the substrate supported on the first substrate support, and the holder is located below the support plate when the second body may be located in the closed position.

According to the exemplary embodiment of the present invention, the first substrate support is fixedly coupled to the first body, the second substrate support is fixedly coupled to the second body, and the first body may be located above the second body.

According to the exemplary embodiment of the present invention, a groove is formed in a region of a lower wall of the chamber corresponding to the holder, and in the closed position, the holder may be located within the groove.

According to the exemplary embodiment of the present invention, a bottom surface adjacent to the treatment space in the lower wall of the chamber includes: a center base surface of a center region of the bottom surface; a groove base surface, which is a bottom surface of the groove; and a floor surface provided higher than the base surface in a region between the center base surface and the groove base surface, and the fluid supply unit may include a fluid supply line that supplies the fluid to a lower supply port formed on the center base surface.

According to the exemplary embodiment of the present invention, the second substrate support may be installed on the floor surface.

According to the exemplary embodiment of the present invention, the second substrate support is larger than an outer diameter of the center base surface and may smaller than an inner diameter of the groove base surface.

According to the exemplary embodiment of the present invention, a region in which the second substrate support supports the substrate may be an inner region than a region in which the first substrate support supports the substrate.

According to the exemplary embodiment of the present invention, when viewed from above, the second substrate support may be located outside the first substrate support.

According to the exemplary embodiment of the present invention, the holder includes: a base; a plurality of extending portions extending from the base; and a plurality of support pins installed on the extending portions, respectively, and on which the substrate is placed, and an upper end of the support pin may be lower than the support plate in the closed position.

According to the exemplary embodiment of the present invention, a diameter of the support plate may be provided to be smaller than a diameter of a circle passing through the support pins when viewed from above.

An exemplary embodiment of the present invention, a method of treating a substrate, the method comprising: a loading operation in which a transfer robot loads a substrate into a treatment space in a state where the treatment space defined by an upper body and a lower body opens; a closing operation of closing the treatment space by moving any one of the upper body and the lower body relative to the other, after the loading operation; and a treating operation of treating the substrate by supplying a fluid to the treatment space, after the closing operation, wherein in the loading operation, the transfer robot places the substrate on a first substrate support coupled to the upper body, and in the treating operation, the substrate is treated in a state where the substrate placed on the first substrate support may be handed over to a second substrate support coupled to the lower body.

According to the exemplary embodiment of the present invention, the handing-over of the substrate from the first substrate support to the second substrate support may be made by moving one of the upper body and the lower body relative to the other.

According to the exemplary embodiment of the present invention, the handing-over of the substrate from the first substrate support to the second substrate support may be made during the closing operation.

According to the exemplary embodiment of the present invention, in the loading operation, the first substrate support is located higher than the second substrate support, and in the treating operation, the first substrate support may be located lower than the second substrate support.

According to the exemplary embodiment of the present invention, in the closing operation, the first substrate support may be located in a groove formed in a lower wall of the lower body.

According to the exemplary embodiment of the present invention, the second substrate support may be installed on a bottom surface extending from an upper portion of the groove.

According to the exemplary embodiment of the present invention, the fluid is supplied through a lower supply port formed in a lower wall of the chamber in the treating operation, and the lower supply port may be formed in a center region of the lower wall of the chamber.

An exemplary embodiment of the present invention, an apparatus for processing a substrate, the apparatus comprising: a chamber for providing a treatment space for processing a substrate; a fluid supply unit for supplying a fluid into the treatment space; an exhaust unit for exhausting the fluid from the treatment space; a first substrate support which is placed in the treatment space and on which a robot transferring the substrate seats the substrate; and a second substrate support which is placed in the treatment space and supports the substrate while the substrate is being treated in the treatment space, wherein the chamber includes: an upper body; a lower body, which is combined with the upper body to define the treatment space; and a lifting member for moving the lower body relative to the upper body, the lifting member moves the lower body between an open position and a closed position, the open position is a position where the substrate is loaded into the treatment space or unloaded from the treatment space by opening the treatment space, the closed position is a position where the treatment space is sealed to treat the substrate, the first substrate support provided to the upper body includes: a plurality of rods installed on the upper body; and a holder which is installed on the rod and on which the substrate is placed, the second substrate support installed on the lower body includes a support plate opposite to the substrate supported on the first substrate support, a groove is formed in a region of a lower wall of the lower body corresponding to the holder, and the holder is located within the groove in the closed position and may be located below the support plate.

According to the exemplary embodiment of the present invention, a bottom surface adjacent to the treatment space in the lower wall of the chamber includes a floor surface formed in a middle region which is a region between a center region of the bottom surface and a base surface, which is a bottom surface of the groove, and provided higher than the base surface, the fluid supply unit includes a fluid supply line that supplies the fluid to a lower supply port formed in a center region of the lower wall of the chamber, and the second substrate support is larger than an outer diameter of the center base surface and smaller than an inner diameter of the groove base surface, and may be installed on the floor surface.

According to the exemplary embodiment of the present invention, the holder includes: a base; a plurality of extending portions extending from the base; and a plurality of support pins installed on the extending portions, respectively, and on which the substrate is placed, and a diameter of the support plate is provided smaller than a diameter of a circle passing through the support pins when viewed from above, and an upper end of the support pin may be lower than the support plate in the closed position.

According to the exemplary embodiment of the present invention, when a substrate is dry treated, the substrate may be uniformly dried.

According to the exemplary embodiment of the present invention, when a substrate is dry treated, the flow of a fluid on the substrate may be uniformly shaped.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating the treatment of a substrate in a typical drying chamber.

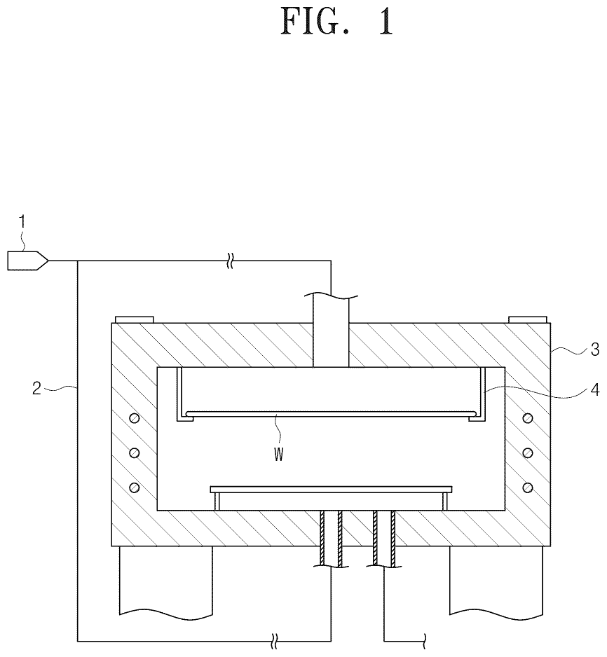

FIG. 2 is a diagram schematically illustrating the flow of a fluid on the substrate of FIG. 1.

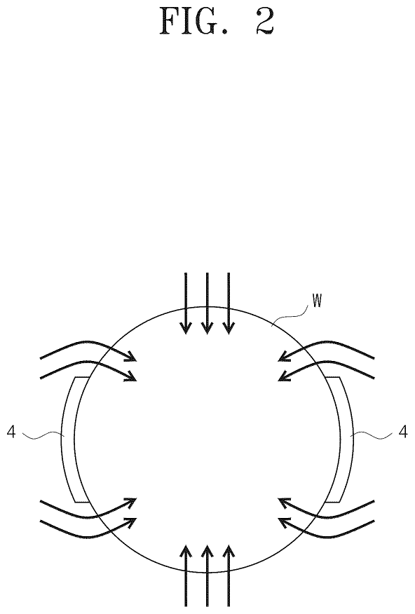

FIG. 3 is a diagram schematically illustrating the exemplary embodiment of a substrate processing apparatus of the present invention.

FIG. 4 is a diagram schematically illustrating an exemplary embodiment of a liquid treating chamber of FIG. 2.

FIG. 5 is a diagram illustrating a phase change graph of carbon dioxide.

FIG. 6 is a diagram schematically illustrating the exemplary embodiment of the drying chamber of FIG. 2.

FIG. 7 is a diagram schematically illustrating a second body located at an open position in a loading operation.

FIG. 8 is a diagram schematically illustrating the second body located at a closed position in a closing operation.

FIG. 9 is a diagram schematically illustrating the flow of a fluid on the substrate in the treating operation.

FIG. 10 is a diagram schematically illustrating another exemplary embodiment of the drying chamber of FIG. 2.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

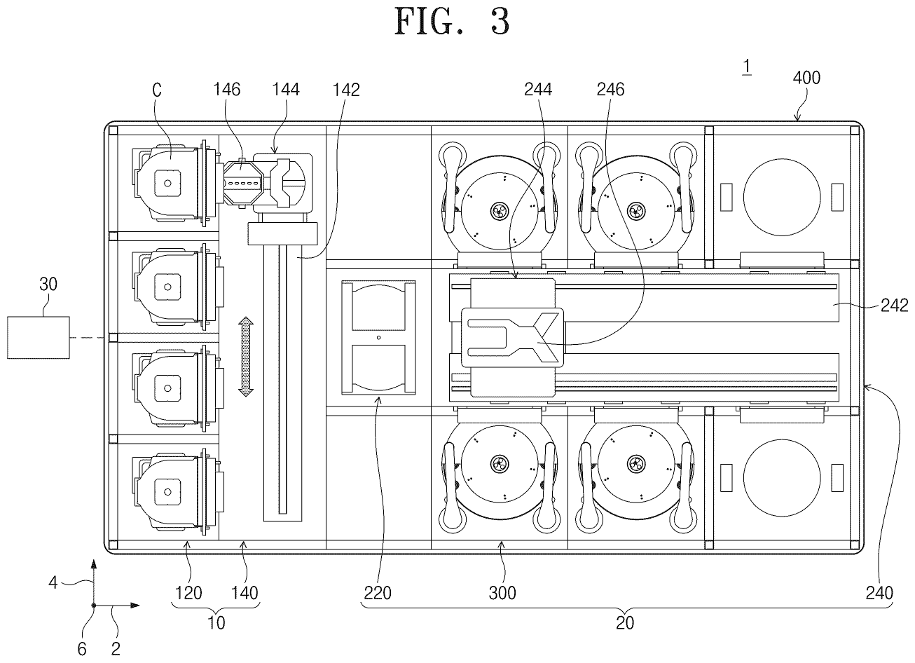

FIG. 3 is a diagram schematically illustrating the exemplary embodiment of a substrate processing apparatus of the present invention. Referring to FIG. 3, the substrate processing apparatus 1 includes an index module 10 and a treating module 20. According to the exemplary embodiment, the index module 10 and the treating module 20 are disposed in one direction. Hereinafter, the direction in which the index module 10 and the treating module 20 are disposed is defined as a first direction 2. When viewed from above, the direction perpendicular to the first direction 2 is defined as a second direction 4, and the direction perpendicular to the plane including both the first direction 2 and the second direction 4 is defined as the third direction 6.

The index module 10 transfers the substrate W from a cassette C in which the substrate W is accommodated to the treating module 20, which treats the substrate W. The index module 10 accommodates the substrate W that has been completely treated in the treating module 20 into the cassette C. A longitudinal direction of the index module 10 is provided in the second direction 4. The index module 10 includes a load port 110 and an index frame 140.

The cassette C, in which the substrate W is accommodated, is seated in the load port 120. The load port 120 is located at an opposite side of the treating module 20 based on the index module 140. A plurality of load ports 120 may be provided. The plurality of load ports 120 may be arranged in a line along the second direction 4. The number of load ports 120 may increase or decrease depending on process efficiency and footprint conditions of the treating module 20.

The cassette C is formed with a plurality of slots (not illustrated). The substrates W may be seated in the slots (not illustrated). The plurality of slots (not illustrated) may be spaced apart from each other in the third direction 6. The substrates W may be seated in the slots (not illustrated), respectively, and accommodated in the cassette C in a horizontally disposed state with respect to the ground.

As the cassette C, an airtight container, such as a Front Open Unified Pod (FOUP), may be used. The cassette C may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided along the second direction 4 in its longitudinal direction in the index frame 140. The index robot 144 may transfer the substrate W. The index robot 144 may transfer the substrate W between the index module 10 and the buffer unit 220, which will be described later.

The index robot 120 includes an index hand 146. On the index hand 146, the substrate W is seated. The index hand 146 may be provided to be movable in the second direction 4 on the index rail 142. Therefore, the index hand 146 is movable forward and backward along the index rail 142. Additionally, the index hand 146 may be provided to be rotatable about the third direction 6 as the axis. Additionally, the index hand 146 may be provided to be vertically movable along the third direction 6. A plurality of index hands 146 may be provided. The plurality of index hands 146 may be provided to be spaced apart from each other in the upward and downward direction. The plurality of index hands 146 may move forwardly, backwardly, and rotationally independently of each other.

The controller 30 may control the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 so as to perform a substrate processing method described below. For example, the controller 30 may control the configurations provided in the drying chamber 400 to perform a substrate processing method described below.

The treating module 20 includes a buffer unit 220, a transfer frame 240, a liquid treating chamber 300, and a drying chamber 400. The buffer unit 220 provides a buffer space where the substrate W loaded into the treating module 20 and the substrate W being unloaded from the treating module 20 temporarily stay. The transfer frame 240 provides a transfer space for transferring the substrate W between the buffer unit 220, the liquid treating chamber 300, and the drying chamber 400.

The liquid treating chamber 300 may perform a liquid treatment process by supplying liquid onto the substrate W to liquid-treat the substrate W. The drying chamber 400 may perform a drying process to remove any remaining liquid on the substrate W. The liquid treating chamber 300 and the drying chamber 400 may perform a cleaning process. The cleaning process may be performed sequentially in the liquid treating chamber 300 and the drying chamber 400. For example, the liquid treating chamber 300 may treat the substrate W by supplying chemicals, rinse solutions, and/or organic solvents onto the substrate W. For example, in the drying chamber 400, a drying treatment may be performed by using a supercritical fluid to remove any residual liquid on the substrate W.

The buffer unit 220 may be disposed between the index frame 140 and the transfer frame 240. The buffer unit 220 may be located at one end of the transfer frame 240. A slot (not illustrated) in which the substrate W is placed is provided inside the buffer unit 220. A plurality of slots (not illustrated) is provided. The plurality of slots (not illustrated) may be spaced apart from each other along the third direction 6. A front face and a rear face of the buffer unit 220 are opened. The front face may be the side facing the index frame 140, and the rear face may be the side facing the transport frame 240. The index robot 144 may approach the buffer unit 220 through the front face, and a transfer robot 244 to be described later may approach the buffer unit 220 through the rear face.

The transfer frame 240 may be provided along the first direction 2 in a longitudinal direction thereof. The liquid treating chamber 300 and the drying chamber 400 may be disposed on both sides of the transfer frame 240. The liquid treating chamber 300 and the drying chamber 400 may be disposed on the lateral portion of the transfer frame 240. The transfer frame 240 and the liquid treating chamber 300 may be disposed along the second direction 4. Further, the transfer frame 240 and the drying chamber 400 may be disposed along the second direction 4.

In one example, the liquid treating chambers 300 are disposed on opposite sides of the transfer frame 240, and the drying chambers 400 are disposed on opposite sides of the transfer frame 240. The liquid treating chambers 300 may be disposed relatively closer to the buffer unit 220 than the drying chambers 400. At one side of the transfer chamber 240, the liquid treating chambers 300 may be provided in an arrangement of A×B (each of A and B is 1 or a natural larger than 1) in the first direction 2 and the third direction 6. Here, A is the number of liquid treating chambers 300 provided in a line along the first direction 2, and B is the number of liquid treating chambers 300 provided in a line along the third direction 6. For example, when four liquid treating chambers 300 are provided on one side of the transfer frame 240, the liquid treating chambers 300 may be arranged in a 2×2 arrangement. The number of liquid treating chambers 300 may be increased or decreased. As described above, the liquid treating chambers 300 may be provided only on one side of the transfer frame 240, and only the drying chambers 400 may be arranged on the other side opposite the one side. Further, the liquid treating chamber 300 and the drying chamber 400 may be provided in a single layer on one side and opposite sides of the transfer frame 240.

The transfer frame 240 includes a guide rail 242 and a transfer robot 244. The guide rail 242 and the transfer robot 244 are provided inside the transfer frame 240. The guide rail 242 may be provided in the first direction 2 along its length. The transfer robot 244 may be provided to be linearly movable in the first direction 2 on the guide rail 242. The transfer robot 244 transfers the substrate W between the buffer unit 220, the liquid treating chamber 300, and the drying chamber 400.

The transfer robot 244 includes a transfer hand 246 on which the substrate W is placed. The transfer hand 246 may be provided to be movable along the first direction 2 on the guide rail 242. Accordingly, the transfer hand 246 is movable forwardly and backwardly along the guide rail 242. In addition, the transfer hand 246 may be provided to be rotatable about the third direction 6 and to be movable along the third direction 6. A plurality of transfer hands 246 may be provided. The plurality of transfer hands 246 may be provided to be spaced apart from each other in the vertical direction. The plurality of transfer hands 246 may move forwardly, backwardly, and rotationally independently of each other.

The liquid treating chamber 300 performs a liquid-treatment process on the substrate W. For example, the liquid treating chamber 300 may be a chamber that performs a cleaning process to remove impurities, such as process byproducts or particles, adhering to the substrate W. The liquid treating chamber 260 may have a different structure depending on the type of process treating the substrate W. Unlike this, each of the liquid treating chambers 300 may have the same structure.

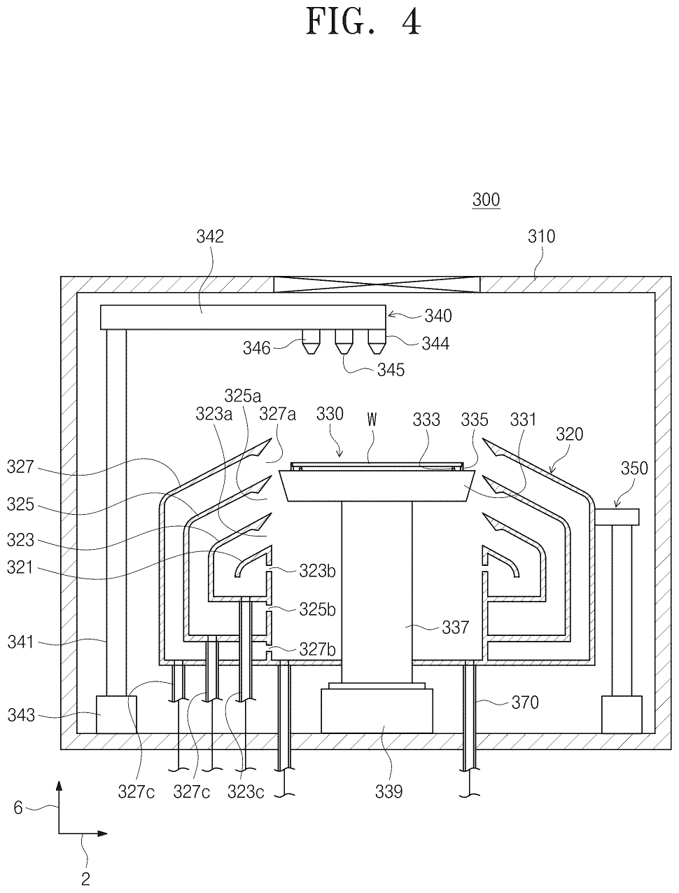

FIG. 4 is a cross-sectional view schematically showing a structure of the liquid treating chamber in FIG. 3. Referring to FIG. 4, the liquid treating chamber 300 includes a chamber 310, a treatment container 320, a support member 330, and a liquid supply unit 340.

The chamber 310 has an interior space. The chamber 310 is provided in a generally cuboidal shape. An opening (not illustrated) is formed in one side of the chamber 310. The opening (not illustrated) functions as an entrance port through which the substrate W is loaded into and unloaded from of the interior space of the chamber 310 by the transfer robot 244. The treatment container 320, the support member 330, and the liquid supply unit 340 are disposed in the interior space of the chamber 310.

The treatment container 320 has a treatment space with an opened upper portion. The treatment container 320 may be a bowl having a treatment space. The treatment container 320 may be provided to surround the treatment space. The treatment space of the treatment container 320 is provided as a space for the substrate W to be supported and rotated by the support member 330 described later. Furthermore, the treatment space is provided as a space for the liquid supply unit 340, described later, to supply a liquid onto the substrate W to treat the substrate W.

According to the example, the treatment container 320 may have a guide wall 321 and a plurality of recovery containers 323, 325, and 327. Each of the recovery containers 323, 325, and 327 separately collects different liquids from the liquids used to treat the substrate W. The recovery containers 323, 325, and 327 may each have a recovery space for recovering the liquid used to treat the substrate W.

The guide wall 321 and the recovery containers 323, 325, and 327 are provided in the form of an annular ring surrounding the support member 330. When a liquid is supplied onto the substrate W, the liquid that is scattered by the rotation of the substrate W may enter the recovery space through the inlets 323a, 325a, and 327a of the recovery containers 323, 325, and 327 described below. Different types of liquid may be introduced into of the recovery containers 323, 325, and 327, respectively.

The treatment container 320 has a guide wall 320, a first recovery container 323, a second recovery container 325, and a third recovery container 327. The guide wall 321 is provided in the shape of an annular ring that surrounds the support member 330. The first recovery container 323 is provided in an annular ring shape surrounding the guide wall 321. The second recovery container 325 is provided in an annular ring shape surrounding the first recovery container 323. The third recovery container 327 is provided in an annular ring shape surrounding the second recovery container 325.

The space between the guide wall 321 and the first recovery container 323 functions as a first inlet 323a through which the liquid is introduced. A space between the first recovery container 323 and the second recovery container 325 functions as a second inlet 325a through which the liquid is introduced. A space between the second recovery container 325 and the third recovery container 327 functions as a third inlet 327a through which the liquid is introduced. The second inlet 325a may be located above the first inlet 323a, and the third inlet 327a may be located above the second inlet 325a. The liquid introduced into the first inlet 323a, the liquid introduced into the second inlet 325a, and the liquid introduced into the third inlet 327a may be different types of liquid.

The space between the bottom of the guide wall 321 and the first recovery container 323 functions as a first outlet 323b, through which impurities and airflow generated from the liquid are discharged. The space between the bottom of the first recovery container 323 and the second recovery container 325 functions as a second outlet 325b, through which impurities and airflow generated from the liquid are discharged. The space between the bottom of the second recovery container 325 and the third recovery container 327 functions as a third outlet 327b, through which impurities and airflow generated from the liquid are discharged. The impurities and airflow discharged from the first outlet 323b, the second outlet 325b, and the third outlet 327b are exhausted to the outside of the liquid treating chamber 300 via the exhaust unit 370 described later.

Recovery lines 323c, 325c, and 327c extending vertically downwardly are connected to the bottom surface of the recovery containers 323, 325, and 327, respectively. The recovery lines 323c, 325c, and 327c discharge the liquids that have been introduced through the recovery containers 323, 325, and 327, respectively. The discharged treatment liquid may be reused via an external liquid reclamation system (not illustrated).

The support member 330 supports and rotates the substrate W within the treatment space. The support member 330 may have a spin chuck 331, a support pin 333, a chuck pin 335, a rotation shaft 337, and a driver 339.

The spin chuck 331 has a top surface that is substantially circular when viewed from the top. The top surface of the spin chuck 331 may have a diameter larger than the substrate W.

A plurality of support pins 333 is provided. The support pin 333 is disposed on the top surface of the spin chuck 331. The support pins 333 are spaced apart at regular intervals at the edge portion of the top surface of the spin chuck 331. The support pins 333 are formed to protrude upwardly from the top surface of the spin chuck 331. The support pins 333 are arranged in combination with each other to form an overall annular ring shape. The support pin 333 supports an edge region of the rear surface of the substrate W so that the substrate W is spaced apart from the top surface of the spin chuck 331 at a predetermined distance.

A plurality of chuck pins 335 is provided. The chuck pins 335 are disposed relatively farther away from the center region of the spin chuck 331 than the support pins 333. The chuck pins 335 protrude upwardly from the top surface of the spin chuck 331. The chuck pin 335 supports a lateral region of the substrate W to prevent the substrate W from laterally deviating from its stationary position when the substrate W is rotated.

The rotation shaft 337 is coupled with the spin chuck 331. The rotation shaft 337 is coupled to the bottom surface of the spin chuck 331. The rotation shaft 337 may be provided with a longitudinal direction facing the third direction 6. The rotation shaft 337 is provided to be rotatable by receiving power from the driver 339. The rotation shaft 337 is rotated by the driver 339, and the spin chuck 331 is rotated by a medium of the rotation shaft 337. The driver 339 rotates the rotation shaft 337. The driver 339 is capable of varying the rotational speed of the rotation shaft 337. The driver 339 may be a motor that provides driving force. However, the driver is not limited thereto, and may be provided in various variations with any known device that provides driving force.

The liquid supply unit 340 supplies the liquid to the substrate W. The liquid supply unit 340 supplies a liquid to the substrate W supported on the support member 330. The liquid supplied to the substrate W by the liquid supply unit 340 may be provided in a plurality of types. The liquid supply unit 340 may include a support rod 341, an arm 342, a driver 343, a first liquid supply nozzle 344, and a second liquid supply nozzle 345.

A support rod 341 is located in the interior space of the chamber 310. The support rod 341 may be located on one side of the treatment container 320 in the interior space. The support rod 2641 may have a rod shape in which a longitudinal direction faces the third direction 6. The support rod 341 is provided to be rotatable by the driver 343 to be described later.

The arm 342 is coupled to an upper end of the support rod 341. The arm 342 extends vertically from the longitudinal direction of the support rod 341. The arm 342 may be provided in the third direction 6 along its length. At the end of the arm 342, the first liquid supply nozzle 344, the second liquid supply nozzle 345, and the third liquid supply nozzle 346 may be fixedly coupled.

The arm 342 may be provided to be movable forwardly and backwardly along its longitudinal direction. The arm 342 may be swing moveable via the support rod 341 by the driver 343 that rotates the support rod 341. By rotation of the arm 342, the first liquid supply nozzle 344, the second liquid supply nozzle 345, and the third liquid supply nozzle 346 may also be swung and moved between a process position and a standby position.

The process position may be a position where any one of the first liquid supply nozzle 344, the second liquid supply nozzle 345, and the third liquid supply nozzle 346 is opposite the substrate W supported on the support member 330. In one example, the process position may be a position where a center of any one of the first liquid supply nozzle 344, the second liquid supply nozzle 345, and the third liquid supply nozzle 346 is opposite a center of the substrate W supported on the support member 330. The standby position may be a position where all of the first liquid supply nozzle 344, the second liquid supply nozzle 345, and the third liquid supply nozzle 346 deviate from the process position.

The driver 343 is coupled with the support rod 341. The driver 343 may be disposed on the bottom surface of the chamber 310. The driver 343 provides driving force for rotating the support rod 341. The driver 343 may be provided as a known motor that provides driving force.

The first liquid supply nozzle 344 supplies a first liquid onto the substrate W. The first liquid supply nozzle 344 may supply the first liquid onto the substrate W supported on the support member 330. The second liquid supply nozzle 345 supplies the second liquid onto the substrate W. The second liquid supply nozzle 345 supplies a second liquid onto the substrate W supported on the support member 330. The third liquid supply nozzle 346 supplies a third liquid onto the substrate W. The third liquid supply nozzle 346 supplies the third liquid onto the substrate W supported on the support member 330.

According to the exemplary embodiment, the first liquid, the second liquid, and the third liquid may be any one of a chemical, a rinse liquid, and an organic solvent. For example, the chemical may include diluted sulfuric acid (H₂SO₄), phosphoric acid (P₂O₅), hydrofluoric acid (HF), and ammonium hydroxide (NH₄OH). For example, the rinse liquid may include water or deionized water (DIW). For example, the organic solvent may include alcohol, such as isopropyl alcohol (IPA). According to the exemplary embodiment, the first liquid may be a chemical. Further, the second liquid may be a rinse liquid. Further, the third liquid may be an organic solvent.

The present invention has been described based on the case where in the liquid supply unit 340 according to the exemplary embodiment of the present invention, the first liquid supply nozzle 344, the second liquid supply nozzle 345, and the third liquid supply nozzle 346 are all coupled to the arm 342, as an example, but the present invention is not limited thereto. For example, each of the first liquid supply nozzle 344, the second liquid supply nozzle 345, and the third liquid supply nozzle 346 may independently have an arm, a support rod, and a driver, and may independently swing and move back and forth to move between a process position and a standby position.

The lifting unit 350 is disposed in the interior space of the chamber 310. The lifting unit 350 adjusts the relative height between the treatment container 320 and the support member 330. The lifting unit 350 may move the treatment container 320 in a straight line in the third direction 6. Accordingly, since the height of the recovery containers 323, 325, and 327 for recovering the liquid is changed according to the type of the liquid supplied to the substrate W, the liquids may be separated and collected. As described above, the treatment container 320 is fixedly installed, and the lifting unit 350 may move the support member 330 in an upward or downward direction to change the relative height between the support member 330 and the treatment container 320.

The exhaust unit 370 exhausts impurities generated in the treatment space. Impurities generated during liquid treatment of the substrate W are exhausted by a pressure reducing unit (not illustrated) provided in the exhaust unit 370. The exhaust unit 370 may be coupled to the bottom surface of the treatment container 320. In one example, the exhaust unit 370 may be disposed in the space between the rotation shaft 337 and the inner wall of the treatment container 320.

The drying chamber 400 may be a process chamber that is sealed from the outside environment. The drying chamber 400 utilizes a process fluid to remove any residual liquid on the substrate W. In one example, the drying chamber 400 uses a supercritical fluid to remove the third liquid (e.g., an organic solvent) that remains on the substrate W. In the drying chamber 400, a supercritical process is performed by using the properties of the supercritical fluid. Representative examples thereof include a supercritical drying process and a supercritical etching process. Hereinafter, the supercritical process will be described based on the supercritical drying process. However, this is for ease of understanding only, and the drying chamber 400 may perform other supercritical processes other than the supercritical drying process. In the exemplary embodiment, the supercritical fluid may be supercritical carbon dioxide (scCO₂).

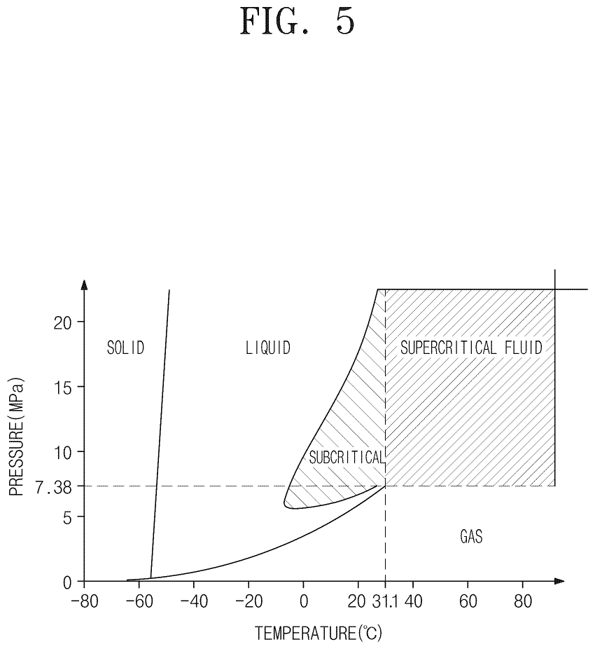

FIG. 5 is a diagram illustrating a phase change graph of carbon dioxide. Referring to FIG. 5, carbon dioxide has a critical temperature of 31.1 É and a relatively low critical pressure of 7.38 MPa, so that carbon dioxide may be easily made to a supercritical state, and it is easy to control phase change of carbon dioxide by adjusting temperature and pressure, and carbon dioxide is low priced. In addition, carbon dioxide is non-toxic and harmless to the human body, and has characteristics of non-combustibility and inertness. Compared with water or other organic solvents, the diffusion coefficient of supercritical carbon dioxide is about 10 to 100 times higher, so that penetration of the supercritical carbon dioxide is fast, and the supercritical carbon dioxide is quickly replaced with the organic solvents. In addition, since supercritical carbon dioxide has almost no surface tension, the supercritical carbon dioxide has advantageous properties to be used for drying the substrate W including a fine circuit pattern. In addition, by-product of various chemical reactions of the supercritical carbon dioxide may be recycled, and at the same time, the supercritical carbon dioxide may be converted into a gas after being used in the supercritical drying process and the organic solvent may be separated and reused, so that there is less burdensome in terms of environmental pollution.

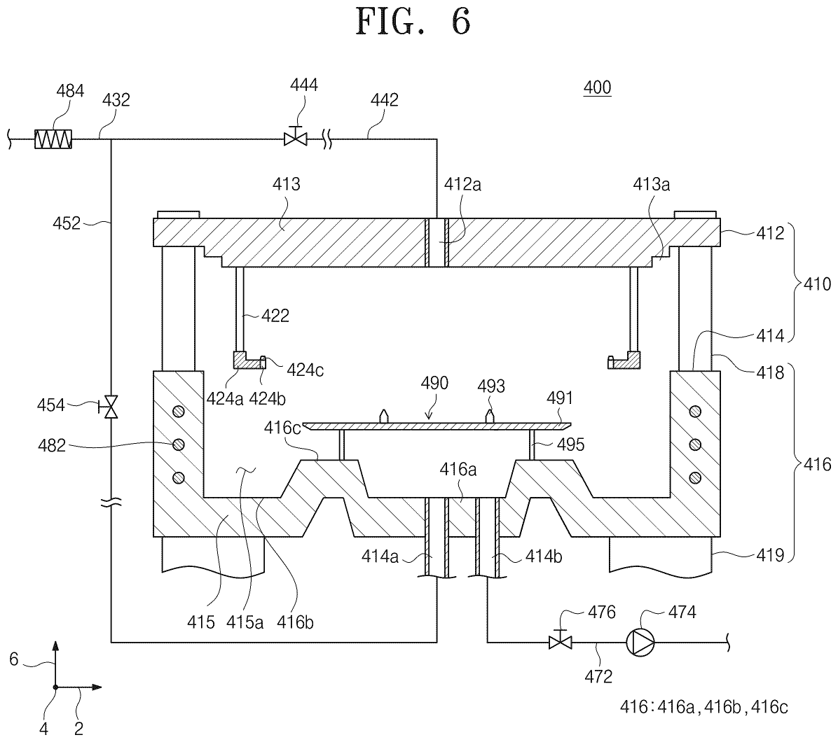

FIG. 6 is a diagram schematically illustrating the exemplary embodiment of the drying chamber of FIG. 3. Referring to FIG. 6, the drying chamber 400 may include a housing 410, a first substrate support 420, a fluid supply unit 430, a fluid discharge unit 470, a heating unit 480, and a second substrate support 490.

The housing 410 has a treatment space 401 therein. In the treatment space 401, a drying treatment may be performed on the substrate W. The housing 410 may include a first body 412, a second body 414, and a lifting member 416.

The first body 412 and the second body 414 are disposed vertically. In the exemplary embodiment, the first body 412 may be located above the second body 414. The first body 412 may be an upper body. The first body 412 and the second body 414 are combined with each other to define the treatment space 401. The first body 412 and the second body 414 may be combined with each other to have a generally cylindrical shape. The first body 412 and the second body 414 can open and close the treatment space 401. The first body 412 and the second body 414 may enclose the treatment space 401.

The first body 412 includes an upper wall 413. A groove 413a may be formed in an edge region of the upper wall 413. The groove 413a may be formed adjacent to the treatment space 401. Further, the first substrate support 420, to be described later, may be installed on the upper wall 413.

The second body 414 may be a lower body. The second body 414 includes a lower wall 415. The lower wall 415 may have a curved cross-section. A groove 415a may be formed in an edge region of the lower wall 415. The groove 415a may be formed in a region of the lower wall 415 that corresponds to the first substrate support 420, which will be described later. In the groove 415a, the first substrate support 420 may be located when the second body 414 is in the closed position.

The lower wall 415 includes a bottom surface 416. The bottom surface 416 may be a side of the lower wall 415 that is adjacent to the treatment space 401. The bottom surface 416 may be a top surface of the lower wall 415. The bottom surface 416 includes a center base surface 416a, a groove base surface 416b, and a floor surface 416c. The center base surface 416a is provided in a center region of the bottom surface 416. The center base surface 416a may be formed with a second supply port 414a and an exhaust port 414b, which will be described later. The diameter of the center base surface 416a may be provided smaller than the diameter of the support plate 491, which will be described later. The groove base surface 416b is formed at an edge region of the bottom surface 416. The groove base surface 416b corresponds to the bottom surface of the surface forming the groove 415a. The groove base surface 416b is provided at the same height as that of the center base surface 416a. The inner diameter of the groove base surface 416b may be provided equal to or larger than the diameter of the support plate 491. The inner diameter of the groove base surface 416b may be provided to be smaller than the diameter of the circle formed by an extending portion 424b, which will be described later. The floor surface 416c is formed between the base surfaces 415a and 415b. The floor surface 416c may be provided higher than the center base surface 416a and the groove base surface 416b with respect to the third direction 6. Accordingly, the floor surface 416c may be provided to protrude from the floor surface 416. The center base surface 416a and the floor surface 416c, and the floor surface 416c and the groove base surface 416b may be connected by an inclined plane. The floor surface 416c may be provided with the second substrate support 490, which is to be described later.

The first body 412 and the second body 414 may have supply ports 412a and 414a formed on the first body 412 and the second body 414, respectively. According to the exemplary embodiment, the first supply port 412a formed on the first body 412 may be formed in a center region of the first body 412 when viewed from the top. Further, the second supply port 414a formed in the second body 414 may be formed in a center region of the second body 414 when viewed from the top. Further, a discharge port 414b may be formed on the second body 414. The discharge port 414b may be formed at a location that is eccentrically located a certain distance from the center axis of the second body 414 when viewed from above. For example, the discharge port 414b may be formed at a position spaced a certain distance from the position where the supply port 414a is formed.

The lifting member 416 moves up and down the second body 414. The lifting member 416 may include a lifting cylinder 419 and a lifting rod 418. The lifting cylinder 419 may be coupled to the second body 414. According to the exemplary embodiment, by coupling the lifting cylinder 419 to the second body 414, the second body 414 may be movable up and down. In contrast, the first body 412 may be fixed in position.

The lifting cylinder 419 can move the second body 414 to the closed position. The closed position is a position in which the second body 414 is engaged with the first body 412 to close the treatment space 401. The lifting cylinder 419 moves the second body 414 to the closed position, bringing the first body 412 and the second body 414 into close contact. The lifting cylinder 419 seals the treatment space 401 from the external environment. Thereby, the pressure in the treatment space 401 can be maintained at a high pressure of the critical pressure or higher while the drying treatment is performed on the substrate W.

The lifting cylinder 419 may move the second body 414 to the open position. The open position is a position where the second body 414 and the first body 412 are spaced apart to load the substrate W into the treatment space 401 or to unload the substrate W from the treatment space 401. The lifting cylinder 419 may move the second body 414 to the open position to make the first body 412 and the second body 414 be spaced apart from each other. When the first body 412 and the second body 414 are spaced apart from each other, the treatment space 401 is open. When the treatment space 401 is opened, the substrate W may be loaded into the treatment space 401, or the substrate W may be unloaded from the treatment space 401. The substrate W loaded into the treatment space 401 may be the substrate W that has been completely liquid treated in the liquid treating chamber 300. For example, the substrate W loaded into the treatment space 401 may be a substrate W having organic solvent residue on its top surface.

The lifting rod 418 generates lifting force. For example, the lifting rod 418 may generate force to move in the third direction 6. The lifting rod 418 may be formed with its longitudinal direction facing the third direction 6. One end of the lifting rod 418 may be inserted into the lifting cylinder 419. The other end of the lifting rod 418 may be coupled to the first body 412. The relative lifting movement of the lifting cylinder 419 and the lifting rod 418 may cause the second body 414 to move in the third direction 6. While the second body 414 is being moved in the vertical direction (e.g., the third direction 6), the lifting rod 418 prevents the first body 412 and the second body 414 from moving in the horizontal direction (e.g., the first direction 2 and the second direction 4). The lifting rod 418 guides the second body 414 in a vertical direction of movement. The lifting rod 418 may prevent the first body 412 and the second body 414 from moving out of a fixed position relative to each other.

In one example of the invention described above, the present invention has been described based on the case where the second body 414 is moved in an upward and downward direction to seal the treatment space 401, but is not limited thereto. For example, the first body 412 and the second body 414 may each be moved in an upward and downward direction, respectively. Further, the first body 412 may be movable in an upward and downward direction, and the second body 414 may be fixed in position.

Unlike the example described above, a single housing 410 having an opening (not illustrated) formed in one side of the housing 410 through which the substrate W is loaded in and from may be provided. The housing 410 may be provided with a door (not illustrated). The door (not illustrated) may be movable in an upward and downward direction to open and close the opening (not illustrated), and to keep the housing 410 in a sealed state.

The first substrate support 420 supports the substrate W within the treatment space 401. The first substrate support 420 may be fixedly installed on the first body 412. The first substrate support 420 may have a fixing rod 422 and a holder 424.

The fixing rod 422 is fixedly installed on the first body 412. The fixing rod 422 may be formed to protrude from the upper wall 413 of the first body 412 towards the treatment space. The fixing rod 422 may have a rod shape. The fixing rod 422 is provided with a longitudinal direction facing up and down. A plurality of fixing rods 422 may be provided. The plurality of fixing rods 422 is spaced apart from each other. The plurality of fixing rods 422 is disposed in a position such that they do not interfere with the substrate W when the substrate W is loaded or unloaded. A holder 424 is coupled to the lower end of the fixing rods 422.

The substrate W is mounted on the holder 424. The holder 424 supports an edge region of a lower surface of the substrate W. The holder 424 supports one side of the edge region of the substrate W, and also supports the other side facing the one side. The holder 424 includes a base 424a, an extending portion 424b, and a support protrusion 424c.

The base 424a is coupled to the fixing rod 422. The base 424a may be provided in an arc shape or a straight shape when viewed from above. The present invention will be described based on the case where the base is provided in an arc shape as an example. An inner diameter of the base 424a may be provided to be larger than a diameter of the substrate W. The base 424a may be provided in a position that does not overlap the substrate W when viewed from above. The base 424a may have a vertical cross-section formed with a horizontal portion and a vertical section. In one example, the vertical cross-section of the base 424a may be provided in a ‘L’ shape. The base 424a may be provided in a plurality. In one example, two bases 424a may be provided. In the following, the present invention has been described based on the case where two bases 424a are provided as an example. The respective bases 424a may be provided at positions facing each other. The respective bases 424a may be provided in shapes that are symmetrical to each other. Each base 424a may be a part of an imaginary ring shape. Further, the base 424a may be coupled with extending portion 424b.

The extending portion 424b has a shape protruding from the base 424a. The extending portion 424b may extend in a direction toward a space surrounded by the fixing rods 422. The extending portion 424b may be provided at both ends of the base 424a. A plurality of extending portions 424b may be provided. According to the example, four extending portions 424b may be provided.

The support protrusion 424c supports a lower surface of the substrate W. The support protrusion 424c is installed on the extending portion 424b. A plurality of support protrusions 424c may be provided. The number of support protrusions 424c may be provided in a number corresponding to the number of extending portions 424b. According to the example, four support protrusions 424c may be provided.

Due to the above-described structure, the entire upper surface area of the substrate W, the center region of the lower surface of the substrate W, and a part of the edge region of the lower surface of the substrate W may be exposed to the fluid supplied to the treatment space 401.

The fluid supply unit 430 supplies a fluid to the treatment space 401 in a treating operation S30 to be described later. In the exemplary embodiment, the fluid may be supercritical carbon dioxide (scCO₂). Hereinafter, for convenience of description, the present invention will be described based on the case where the fluid supply unit 430 supplies a supercritical fluid including supercritical carbon dioxide (scCO₂) to the treatment space 401 as an example.

Referring back to FIG. 6, the fluid supply unit 430 may include a main supply pipe 432, a first fluid supply unit 440, and a second fluid supply unit 450.

The main supply pipe 432 may supply a supercritical fluid to the first fluid supply unit 440 and the second fluid supply unit 450. One end of the main supply pipe 432 is connected to a storage source (not illustrated) in which the supercritical fluid is stored. According to the exemplary embodiment, the storage source (not illustrated) may be a reservoir. The other end of the main supply pipe 432 may be branched into a first supply pipe 442 and a second supply pipe 452 to be described later. A second heater 484 to be described later may be installed in the main supply pipe 432.

The first fluid supply unit 440 supplies a supercritical fluid to the treatment space 401. The first fluid supply unit 440 supplies a supercritical fluid to the treatment space 401 via a first supply port 412a formed in the first body 412. According to the exemplary embodiment, the first fluid supply unit 440 may supply a supercritical fluid to an upper region of the treatment space 401. The first fluid supply unit 440 may supply a supercritical fluid in a direction toward the upper surface of the substrate W supported by the support unit 430.

The first fluid supply unit 440 may include a first supply pipe 442 and a first valve 444. One end of the first supply pipe 442 is branched from the main supply pipe 432. The other end of the first supply pipe 442 is connected to the first supply port 412a. The first supply pipe 442 receives a supercritical fluid from the main supply pipe 432 and supplies the supercritical fluid to the treatment space 401 through the first supply port 412a.

The first valve 444 is installed at the first supply pipe 442. The first valve 444 may be provided as an opening/closing valve capable of selectively opening and closing the first supply pipe 442. When the first valve 444 is opened, the supercritical fluid stored in the storage source (not illustrated) may be supplied to the treatment space 401 via the main supply pipe 432, the first supply pipe 442, and the first supply port 412a.

The first valve 444 is installed at the first supply pipe 442. The first valve 444 may be provided as an opening/closing valve capable of selectively opening and closing the first supply pipe 442. When the first valve 444 is opened, the supercritical fluid stored in the storage source (not illustrated) may be supplied to the treatment space 401 through the main supply pipe 442, the first supply pipe 442, and the upper supply port 412a.

In the above-described example, the present invention has been described based on the case where the first valve 444 is the opening/closing valve, but the present invention is not limited thereto, and the first valve 444 may be a flow rate control valve. As the flow rate control valve adjusts the flow rate inside the first supply pipe 442, the flow rate per unit time of the supercritical fluid supplied to the treatment space 401 may be changed. The flow rate per unit time of the supercritical fluid supplied to the treatment space 401 may be changed so that the pressure by the supercritical fluid inside the first supply pipe 432 and inside the treatment space 401 may be changed.

The second fluid supply unit 450 supplies a supercritical fluid to the treatment space 401. The second fluid supply unit 450 supplies a supercritical fluid to the treatment space 401 via the second supply port 414a formed in the second body 414. According to the exemplary embodiment, the second fluid supply unit 450 may supply a supercritical fluid to a lower region of the treatment space 401. The second fluid supply unit 450 may supply a supercritical fluid in a direction toward a lower surface of the substrate W supported by the second substrate support 490.

The second fluid supply unit 450 may include a second supply pipe 452 and a second valve 454. One end of the second supply pipe 452 is branched from the main supply pipe 432. The other end of the second supply pipe 452 is connected to the second supply port 414a. The second supply pipe 452 receives the supercritical fluid from the main supply pipe 432 and supplies the received supercritical fluid to the treatment space 401 through the second supply port 414a.

The second valve 454 is installed in the second supply pipe 452. The second valve 454 may be provided as an opening/closing valve that selectively opens and closes the second supply pipe 452. When the second valve 454 is opened, the supercritical fluid stored in the storage source (not illustrated) may be supplied to the treatment space 401 via the main supply pipe 432, the second supply pipe 452, and the second supply port 414a.

In the foregoing example, the present invention has been described based on the case where the second valve 454 is the opening/closing valve as an example, but the present invention is not limited thereto, and the second valve 454 may be a flow rate control valve. As the flow rate control valve adjusts the open flow rate, the flow rate per unit time of the supercritical fluid supplied to the treatment space 401 may be changed. The flow rate per unit time of the supercritical fluid supplied to the treatment space 401 is changed so that the pressure by the supercritical fluid inside the second supply pipe 452 and inside the treatment space 401 may be changed.

The above-described flow rate control valves may be provided as a metering valve. Optionally, the flow rate control valve may be provided as a pendulum valve or a buffer fly valve. However, the type of the flow rate control valve is not limited thereto, and may be variously modified and provided as a known flow rate control valve capable of controlling a flow rate of a fluid. In the foregoing example, the present invention has been described based on the case where the first valve 444 and the second valve 454 are provided as flow rate control valves, but the present invention is not limited thereto, and the first valve 444 and the second valve 454 may be provided as opening and closing valves, and a first flow rate control valve (not illustrated) and a second flow rate control valve (not illustrated) may be separately provided.

The fluid discharge unit 470 exhausts the atmosphere of the treatment space 401. Also, the fluid discharge unit 470 discharges the supercritical fluid supplied to the treatment space 401. The fluid discharge unit 470 may include a discharge pipe 472, a pressure reducing member 474, and a discharge valve 476.

One end of the discharge pipe 472 is connected to the discharge port 414b formed in the second body 414. The other end of the discharge pipe 472 is connected to the pressure reducing member 474. The pressure reducing member 474 may be provided as a motor that provides negative pressure. The supercritical fluid supplied to the treatment space 401 is sequentially discharged to the outside of the housing 410 through the discharge port 414b and the discharge pipe 472. Also, the discharge valve 476 is installed in the discharge pipe 472. The discharge valve 476 may be provided as an opening/closing valve.

The heating unit 480 changes the temperature of the supercritical fluid. According to the exemplary embodiment, the heating unit 480 may be provided as a heater. The heating unit 480 may include a first heater 482 and a second heater 484.

According to the exemplary embodiment, the first heater 482 may be installed on a sidewall of the housing 410. For example, the first heater 482 may be buried inside a sidewall of at least one of the first body 412 and the second body 414. The first heater 482 may change the temperature of the supercritical fluid flowing through the treatment space 401 by changing the temperature of the treatment space 401. The first heater 482 may heat the supercritical fluid supplied to the treatment space 401 to a critical temperature or higher and maintain a supercritical fluid phase. Furthermore, when the supercritical fluid supplied to the treatment space 401 is liquefied, the first heater 482 may heat the supercritical fluid supplied to the treatment space 401 so as to change the phase to the supercritical phase again.

According to the exemplary embodiment, the second heater 484 may be installed in the fluid supply unit 430. For example, the second heater 484 may be installed in the main supply pipe 432. The second heater 484 may change the internal temperature of the main supply pipe 432 to change the temperature of the supercritical fluid flowing inside the main supply pipe 432. The second heater 484 may heat the supercritical fluid flowing inside the main supply pipe 432 to a critical temperature or higher and maintain the supercritical fluid phase. Also, when the supercritical fluid flowing inside the main supply pipe 432 is liquefied, the second heater 484 may increase the internal temperature of the main supply pipe 432 to change to the supercritical phase again.

In the above example, the present invention has been described based on the case where the second heater 484 is installed in the main supply pipe 432 as an example, but the present invention is not limited thereto. For example, the second heater 484 may be installed in at least one of the main supply pipe 432, the first supply pipe 442, and the second supply pipe 452.

The second substrate support 490 supports the substrate W. The second substrate support 490 supports the substrate W supported by the first substrate support 420. The second substrate support 490 supports the substrate W at a higher height than the first substrate support 420. The second substrate support 490 supports the substrate W when the second body 414 is changed from the open position to the closed position. The second substrate support 490 includes a support plate 491, a support pin 493, and a support rod 495.

The support plate 491 may be provided as a circular plate. A diameter of the support plate 491 may be larger than a diameter of the center base surface 416a. The diameter of the support plate 491 may be smaller than the diameter of the substrate W. The support plate 491 may be provided in a size that does not interfere with the extending portion 424b when the second body 414 moves to the closed position. According to an example, the diameter of the support plate 491 may be smaller than the diameter of a circle formed by a plurality of extending portions 424b.

The support plate 491 is disposed in the treatment space 401. The support plate 491 may be disposed on the path of the supercritical fluid supplied from the second supply port 414a. When viewed from above, the support plate 491 may be installed at a position overlapping the second supply port 414a and the discharge port 414b formed in the second body 414. The support plate 491 may prevent the supercritical fluid supplied from the second supply port 414a from being directly discharged toward the substrate W and preventing the bottom surface of the substrate W from being damaged.

The support pin 493 supports a bottom surface of the substrate W. The support pin 493 is provided on an upper surface of the support plate 491. According to the example, the support pin 493 may be disposed to support a center region of the substrate W. The support pins 493 may be provided in plurality. A plurality of support pins 493 are disposed to be spaced apart from each other by a predetermined distance.

A support rod 495 is coupled to a lower end of the support plate 491. The support rod 495 is installed to have a longitudinal direction in the vertical direction. According to the example, the support rod 495 may be provided in a rod shape. The plurality of support rods 495 may be provided. The plurality of support rods 495 are disposed to be spaced apart from each other by a predetermined distance. The support rod 495 is coupled to the bottom surface 416 of the second body 414. The support rod 495 is coupled to the floor surface 416c. The support rod 495 is provided with a length in which the support plate 491 is spaced apart from the second supply port 414a. Furthermore, the support rod 495 is provided with a length in which the support pin 495 supports the substrate W at a higher position than the first substrate support 420 when the second body 414 is located in the closed position.

Hereinafter, the substrate processing method according to the exemplary embodiment of the present invention will be described in detail. The substrate processing method described below may be performed in the drying chamber 400. Further, the controller 30 may perform the substrate processing method described below by controlling the components of the drying chamber 400.

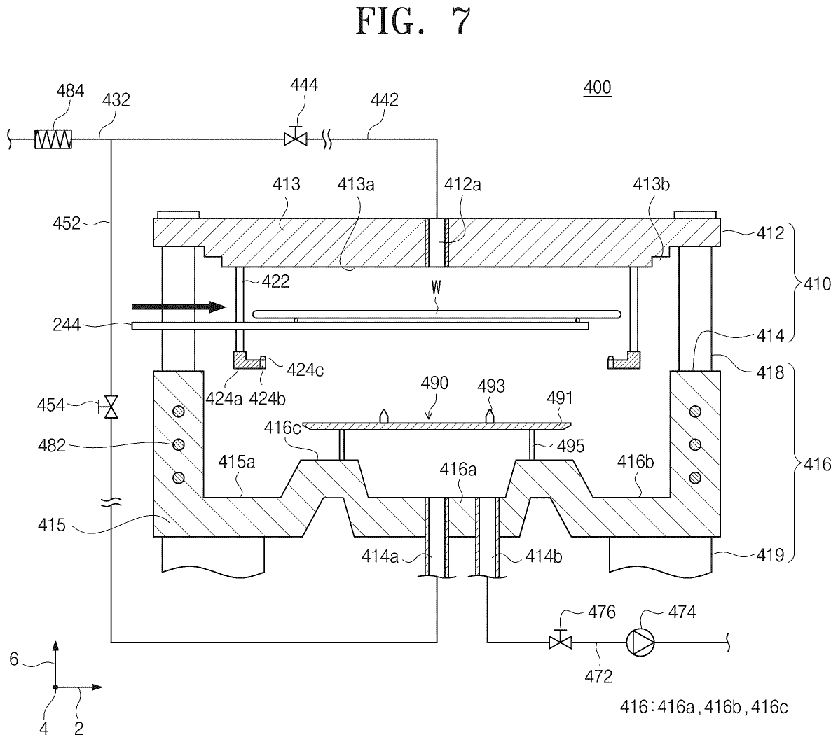

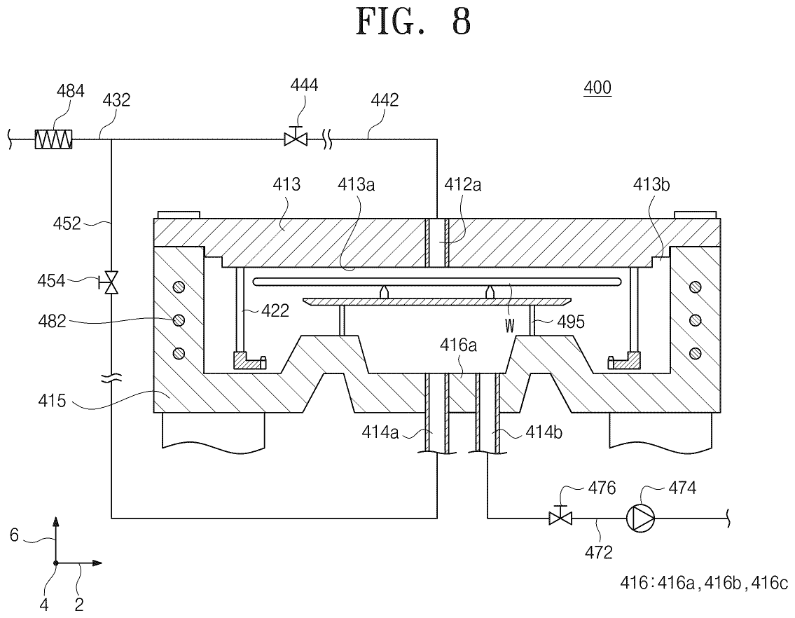

The substrate processing method includes a loading operation S10, a closing operation S20, and a treating operation S30. FIG. 7 is a diagram schematically illustrating the second body located in the open position in the loading operation, and FIG. 8 is a diagram schematically illustrating the second body located in the closed position in the closing operation.

Referring to FIG. 7, the loading operation S10 is an operation of loading a substrate W into the treatment space 401. In the loading operation S10, the second body 414 is lowered to the open position. In the loading operation S10, the treatment space 401 is opened. Thereafter, the transfer robot 244 loads the substrate W into the treatment space W. The transfer robot 244 enters the treatment space 401. FIG. 7 illustrates that the transfer robot 244 enters the treatment space 401 in the first direction 2 for helping understanding. However, the present invention is not limited thereto, and the transfer robot 244 may also enter the treatment space 401 in the second direction 4. The carrying robot 244 hands over the substrate W to the first substrate support 420. The transfer robot 244 is withdrawn from the treatment space 401, and the substrate W is supported by the first substrate support 420. Thereafter, the closing operation S20 may be performed.

Referring to FIG. 8, the closing operation S20 is an operation of closing the treatment space 401. In the closing operation S20, the second body 414 ascends. In the closing operation S20, the second body 414 moves to the closed position. Accordingly, the second body 414 seals the treatment space 401 together with the first body 412.

When the second body 414 ascends, the second substrate support 490 ascends together. The second substrate support 490 lifts the substrate W while ascending. The substrate W is moved from the first substrate support 420 to the second substrate support 490. Accordingly, the substrate W is supported by the second substrate support 490. Also, the first substrate support 420 is located in a groove 415b formed in the lower wall 415. Thereafter, the treating operation S30 may be performed.

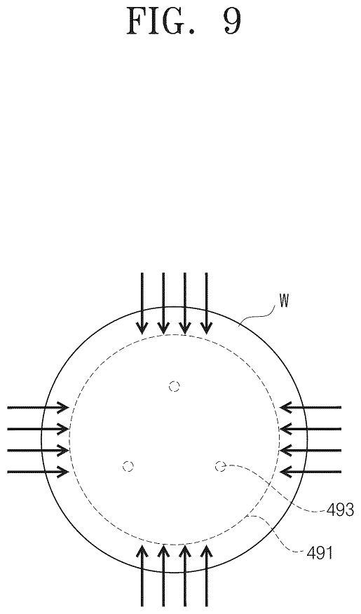

FIG. 9 is a diagram schematically illustrating the flow of a fluid on the substrate in the treating operation. Referring to FIG. 9, the treating operation S30 is an operation of treating the substrate W with a fluid. The fluid may be a fluid containing carbon dioxide. According to the exemplary embodiment, the fluid may be a supercritical fluid. The fluid may be preferentially supplied from the second supply port 414a. Accordingly, the pressure of the treatment space 401 may be increased. Thereafter, when the pressure of the treatment space 401 becomes a predetermined pressure or higher, the fluid may be supplied from the first supply port 412a. Thereafter, when the fluid is sufficiently supplied, the substrate W is treated by the fluid. According to the example, a liquid film formed on the substrate W may be dried. The liquid film may contain an organic solvent. The organic solvent may be isopropyl alcohol (IPA).

According to the exemplary embodiment of the present invention, since the first substrate support 420 is located in the groove 415b of the lower body 414 when the substrate W is treated, the fluid may uniformly flow to the substrate W without interference from the first substrate support 420. A fluid flows uniformly over the substrate W, and thus in-plane treatment uniformity of the substrate W may be improved.

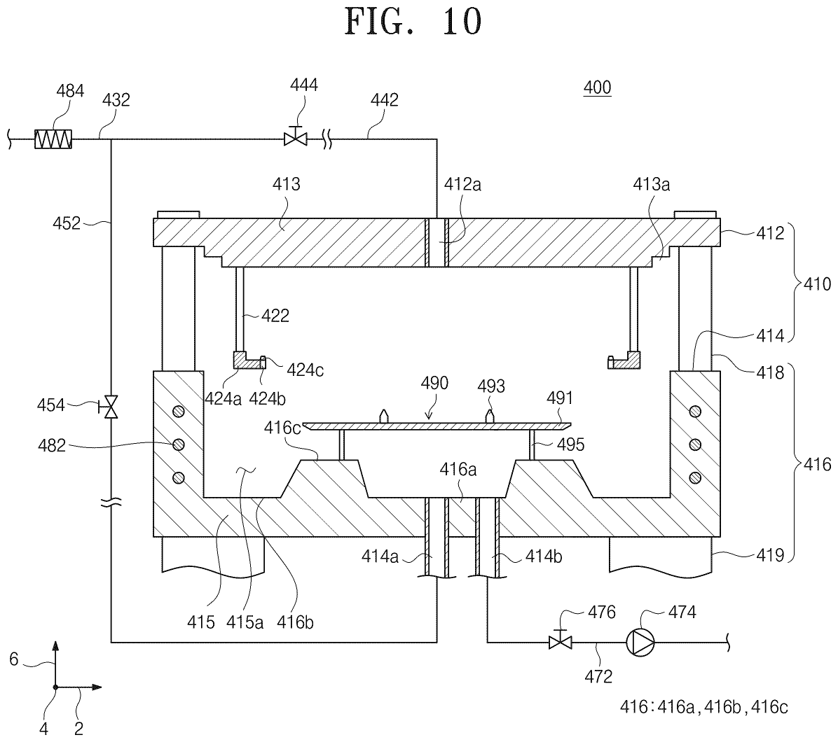

In the above-described example, the present invention has been described based on the case where the lower wall 415 is provided in a curved shape as an example. However, the present invention is not limited thereto, and the lower wall 415 may be provided in a shape in which the floor surface 416c protrudes as illustrated in FIG. 10.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a chamber for providing a treatment space for processing a substrate;
a fluid supply unit for supplying a fluid into the treatment space;
an exhaust unit for exhausting the fluid from the treatment space;
a first substrate support which is placed in the treatment space and on which a robot transferring the substrate seats the substrate; and
a second substrate support which is placed in the treatment space and supports the substrate while the substrate is being treated in the treatment space,
wherein the chamber includes:
a first body;
a second body that is combined with the first body to define the treatment space; and
a lifting member for moving the second body relative to the first body, and
the lifting member moves the second body between an open position and a closed position,
the open position is a position where the substrate is loaded into the treatment space or unloaded from the treatment space by opening the treatment space,
the closed position is a position where the treatment space is sealed to treat the substrate,
the first substrate support includes:
a plurality of fixing rods installed in the chamber; and
a holder which is installed on the rod and on which the substrate is placed,
the second substrate support includes a support plate opposite to the substrate supported on the first substrate support, and
the holder is located below the support plate when the second body is located in the closed position.

2. The apparatus of claim 1, wherein the first substrate support is fixedly coupled to the first body,
the second substrate support is fixedly coupled to the second body, and
the first body is located above the second body.

3. The apparatus of claim 2, wherein a groove is formed in a region of a lower wall of the chamber corresponding to the holder, and
in the closed position, the holder is located within the groove.

4. The apparatus of claim 3, wherein a bottom surface adjacent to the treatment space in the lower wall of the chamber includes:
a center base surface of a center region of the bottom surface;
a groove base surface, which is a bottom surface of the groove; and
a floor surface provided higher than the base surface in a region between the center base surface and the groove base surface, and
the fluid supply unit includes a fluid supply line that supplies the fluid to a lower supply port formed on the center base surface.

5. The apparatus of claim 4, wherein the second substrate support is installed on the floor surface.

6. The apparatus of claim 5, wherein the second substrate support is larger than an outer diameter of the center base surface and smaller than an inner diameter of the groove base surface.

7. The apparatus of claim 1, wherein a region in which the second substrate support supports the substrate is an inner region than a region in which the first substrate support supports the substrate.

8. The apparatus of claim 7, wherein when viewed from above, the second substrate support is located outside the first substrate support.

9. The apparatus of claim 8, wherein the holder includes:
a base;
a plurality of extending portions extending from the base; and
a plurality of support pins installed on the extending portions, respectively, and on which the substrate is placed, and
an upper end of the support pin is lower than the support plate in the closed position.

10. The apparatus of claim 9, wherein a diameter of the support plate is provided to be smaller than a diameter of a circle passing through the support pins when viewed from above.

11-17. (canceled)

18. An apparatus for processing a substrate, the apparatus comprising:
a chamber for providing a treatment space for processing a substrate;
a fluid supply unit for supplying a fluid into the treatment space;
an exhaust unit for exhausting the fluid from the treatment space;
a first substrate support which is placed in the treatment space and on which a robot transferring the substrate seats the substrate; and
a second substrate support which is placed in the treatment space and supports the substrate while the substrate is being treated in the treatment space,
wherein the chamber includes:
an upper body;
a lower body, which is combined with the upper body to define the treatment space; and
a lifting member for moving the lower body relative to the upper body,
the lifting member moves the lower body between an open position and a closed position,
the open position is a position where the substrate is loaded into the treatment space or unloaded from the treatment space by opening the treatment space,
the closed position is a position where the treatment space is sealed to treat the substrate,
the first substrate support provided to the upper body includes:
a plurality of rods installed on the upper body; and
a holder which is installed on the rod and on which the substrate is placed,
the second substrate support installed on the lower body includes a support plate opposite to the substrate supported on the first substrate support,
a groove is formed in a region of a lower wall of the lower body corresponding to the holder, and
the holder is located within the groove in the closed position and is located below the support plate.

19. The apparatus of claim 18, wherein a bottom surface adjacent to the treatment space in the lower wall of the chamber includes a floor surface formed in a middle region which is a region between a center region of the bottom surface and a base surface, which is a bottom surface of the groove, and provided higher than the base surface,
the fluid supply unit includes a fluid supply line that supplies the fluid to a lower supply port formed in a center region of the lower wall of the chamber, and
the second substrate support is larger than an outer diameter of the center base surface and smaller than an inner diameter of the groove base surface, and is installed on the floor surface.

20. The apparatus of claim 19, wherein the holder includes:
a base;
a plurality of extending portions extending from the base; and
a plurality of support pins installed on the extending portions, respectively, and on which the substrate is placed, and
a diameter of the support plate is provided smaller than a diameter of a circle passing through the support pins when viewed from above, and
an upper end of the support pin is lower than the support plate in the closed position.
